(19) United States
(12) Patent Application Publication
(10) Pub. No.: US 2025/0389532 A1
(43) Pub. Date: Dec. 25, 2025

(54) TEST DEVICE AND METHOD OF OPERATING THE SAME

(71) Applicant: Samsung Electronics Co., Ltd., Suwon-si (KR)

(72) Inventors: Minwoo JEON, Suwon-si (KR); Kang Gyune LEE, Suwon-si (KR)

(73) Assignee: Samsung Electronics Co., Ltd., Suwon-si (KR)

(21) Appl. No.: 19/058,562

(22) Filed: Feb. 20, 2025

(30) Foreign Application Priority Data
Jun. 21, 2024 (KR) 10-2024-0081038

(51) Int. Cl. G01B 11/24; H04N 13/106; H04N 13/204; H04N 13/296; H04N 23/60

(52) U.S. Cl. CPC G01B 11/24; H04N 13/106; H04N 13/204; H04N 13/296; H04N 23/64

(57) ABSTRACT

A test device including a first image capture device, a plurality of second image capture devices, and a processor may be provided. The first image capture device captures a semiconductor substrate including a plurality of semiconductor dies and generates two-dimensional image data. Each of the plurality of second image capture devices captures the semiconductor substrate and generates three-dimensional image data when activated. The processor activates one of the plurality of second image capture devices based on process scenario information related to semiconductor post-processes, the semiconductor post-processes including a marking process for the plurality of semiconductor dies, and generates final three-dimensional image data for performing the marking process based on the two-dimensional image data and the three-dimensional image data.

### CROSS-REFERENCE TO RELATED APPLICATIONS

This application claims priority under 35 U.S.C. § 119 to Korean Patent Application No. 10-2024-0081038 filed on Jun. 21, 2024, in the Korean Intellectual Property Office, the disclosure of which is incorporated by reference herein in its entirety.

### BACKGROUND

Example embodiments of the present disclosure described herein relate to electronic devices, and more particularly, relate to test devices and/or an operating methods of the test device.

In semiconductor post-processes, a back-grinding process, a wafer cutting process, a die attaching process, an interconnection process, a molding process, a marking process, a mounting process, and/or a singulation process may be sequentially performed.

Nowadays, as the degree of integration of a semiconductor device is increasing, efforts are continuously made to reduce or prevent errors which may occur in the semiconductor post-processes, and in particular, research is being conducted to accurately identify a distortion, a bending, and the like of semiconductor dies after the molding process and before the marking process.

### SUMMARY

Some example embodiments of the present disclosure provide test devices which generate test result data capable of accurately identifying a distortion, a bending, and the like of semiconductor dies.

Some example embodiments of the present disclosure provide operating methods of the test device.

According to an example embodiment, a test device may include a first image capture device configured to capture a semiconductor substrate including a plurality of semiconductor dies and generate two-dimensional image data, a plurality of second image capture devices each configured to capture the semiconductor substrate and generate three-dimensional image data when activated, and a processor configured to activate one of the plurality of second image capture devices based on process scenario information related to semiconductor post-processes, the semiconductor post-processes including a marking process for the plurality of semiconductor dies, and generate final three-dimensional image data for performing the marking process based on the two-dimensional image data and the three-dimensional image data.

According to an example embodiment, a method of operating a test device may include activating a first image capture device, activating one of a plurality of second image capture devices based on process scenario information related to semiconductor post-processes, the semiconductor post-processes including a marking process for a plurality of semiconductor dies, generating two-dimensional image data by the first image capture device, generating three-dimensional image data are generated by the activated one of the plurality of second image capture device, and generating final three-dimensional image data for performing the marking process based on the two-dimensional image data and the three-dimensional image data.

According to an example embodiment, a test device may include a first image capture device, a plurality of second image capture devices, and a processor. The first image capture device may capture a semiconductor substrate including a plurality of semiconductor dies and generate two-dimensional image data. Each of the plurality of second image capture devices may capture the semiconductor substrate and generate three-dimensional image data when activated. The processor may activate one of the plurality of second image capture devices based on an execution time of a marking process for the plurality of semiconductor dies and a plurality of reference times, and generate final three-dimensional image data for performing the marking process based on the two-dimensional image data and the three-dimensional image data.

### BRIEF DESCRIPTION OF THE DRAWINGS

The above and other advantages and features of the present disclosure will become apparent by describing in detail some example embodiments thereof with reference to the accompanying drawings.

FIG. 1 is a block diagram illustrating a test device according to an example embodiment of the present disclosure.

FIG. 2A is a diagram for explaining a semiconductor substrate of FIG. 1, according to an example embodiment, and FIG. 2B is a diagram for explaining a semiconductor die of FIG. 1, according to an example embodiment.

FIG. 3 is a flowchart illustrating an operating method of the test device of FIG. 1, according to an example embodiment.

FIG. 4 is a diagram for explaining a first image capture device and a plurality of second image capture devices of FIG. 1, according to an example embodiment.

FIG. 5 is a diagram for explaining a target post-process execution time included in process scenario information of FIG. 1, according to an example embodiment.

FIG. 6 is a diagram for explaining a change in a target post-process execution time of FIG. 5, according to an example embodiment.

FIG. 7 is a diagram for explaining a reference time related to a marking process of FIG. 6, according to an example embodiment.

FIG. 8 is a diagram explaining that a processor of FIG. 1 activates one of a plurality of second image capture devices based on a reference time of FIG. 7, according to an example embodiment.

FIG. 9 is a flowchart illustrating an operating method of the test device of FIG. 1, according to an example embodiment.

FIG. 10 is a diagram for explaining reference times related to the marking process of FIG. 9, according to an example embodiment.

FIG. 11 is a flowchart illustrating an operating method of the test device of FIG. 1, according to an example embodiment.

FIG. 12 is a diagram for explaining a movement of a second image capture device in association with an increase in the number of capturing times of FIG. 11.

FIG. 13 is a flowchart illustrating an operating method of the test device of FIG. 1, according to an example embodiment.

FIG. 14 is a diagram for explaining image processing algorithms associated with image processing of FIG. 13.

FIG. 15 is a diagram illustrating an operating method of the test device of FIG. 1, according to an example embodiment.

FIG. 16 is a flowchart illustrating an operating method of a test device and subsequent operations, according to an example embodiment of the present disclosure.

### DETAILED DESCRIPTION

Hereinafter, some example embodiments of the present disclosure will be described clearly and in detail so that a person skilled in the technical field of the present disclosure may easily practice the example embodiments of the present disclosure.

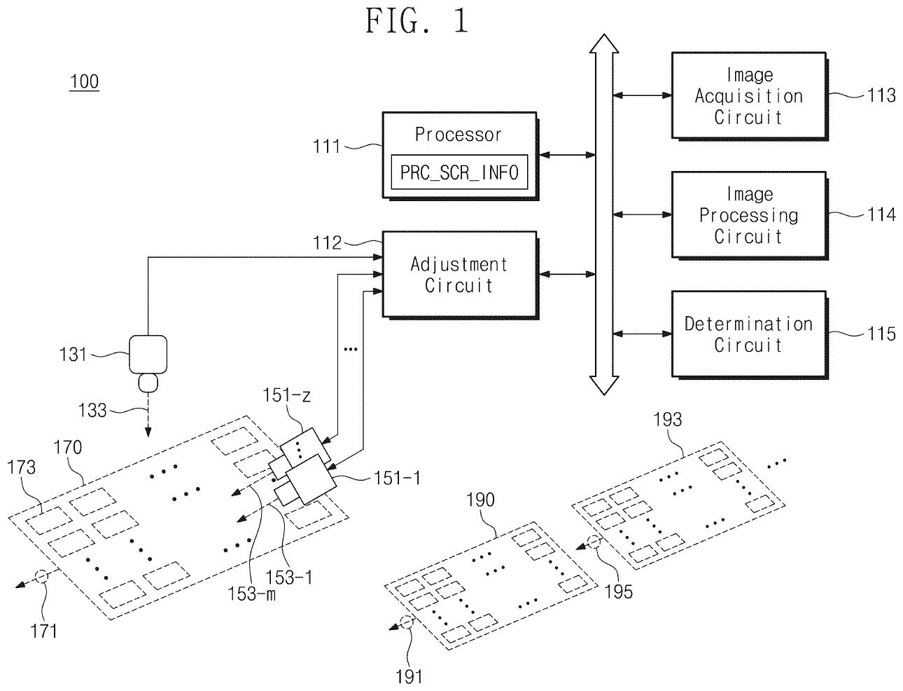

FIG. 1 is a block diagram illustrating a test device according to an example embodiment of the present disclosure.

Referring to FIG. 1, a test device 100 may include a first image capture device 131, a plurality of second image capture devices 151-1 to 151-z (“Z” being an integer greater than or equal to 2), and a processor 111.

The first image capture device 131 may generate two-dimensional image data by capturing a semiconductor substrate 170 including a plurality of semiconductor dies 173.

Each of the plurality of second image capture devices 151-1 to 151-z may generate three-dimensional image data by capturing the semiconductor substrate when activated.

The processor 111 may activate one of the plurality of second image capture devices 151-1 to 151-z based on process scenario information PRC_SCR_INFO related to semiconductor post-processes including a marking process for the plurality of semiconductor dies, and may generate final three-dimensional image data for performing the marking process based on the two-dimensional image data and the three-dimensional image data.

In an example embodiment, the plurality of semiconductor dies may be semiconductor dies after a molding process among the semiconductor post-processes is performed on the plurality of semiconductor dies. For example, the plurality of semiconductor dies may be semiconductor dies placed at a time point after the molding process and before the marking process in the semiconductor post-processes. For example, the plurality of semiconductor dies may be mounted on the semiconductor substrate in a matrix form, but example embodiments of the present disclosure are not limited thereto.

In an example embodiment, the processor 111 may activate the first image capture device 131 and may activate only one of the plurality of second image capture devices 151-1 to 151-z based on the process scenario information PRC_SCR_INFO, and the first image capture device 131 and the activated second image capture device may capture the semiconductor substrate under the control of the processor 111. For example, the first image capture device 131 may generate the two-dimensional image data by capturing the semiconductor substrate in a first direction 133 from an upper end of the semiconductor substrate, and the activated second image capture device may generate the three-dimensional image data by capturing the semiconductor substrate in second directions 153-1 and 153-m from an upper end of the semiconductor substrate. For example, the two-dimensional image data generated by the first image capture device 131 may correspond to a top view, and the three-dimensional image data generated by the activated second image capture device may correspond to an oblique view.

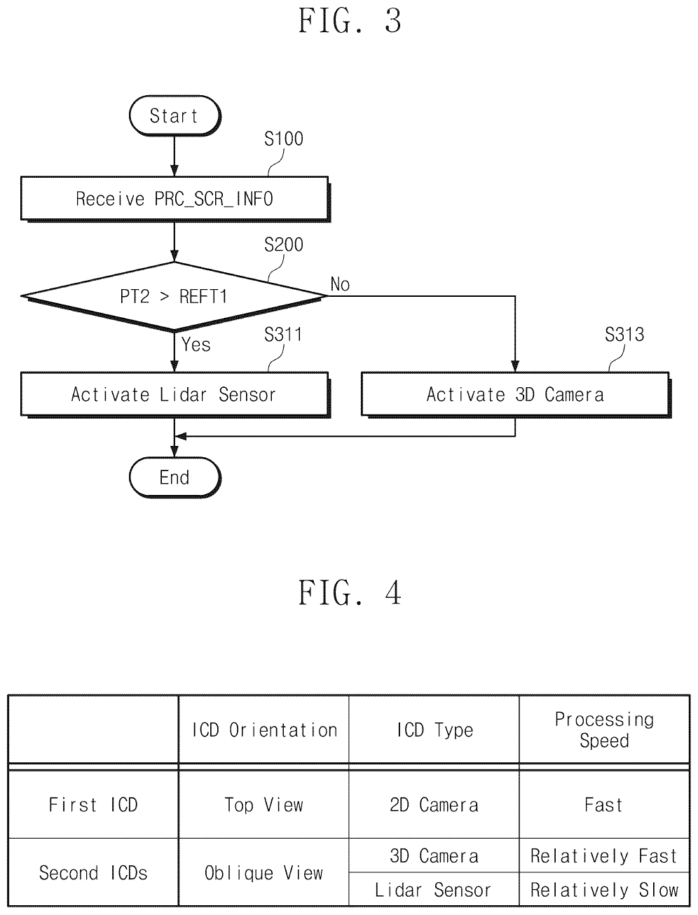

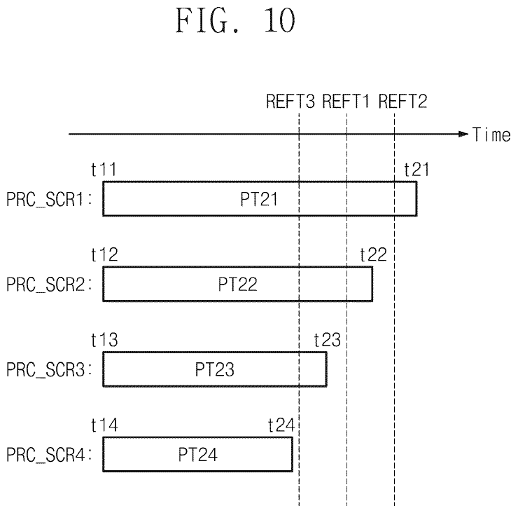

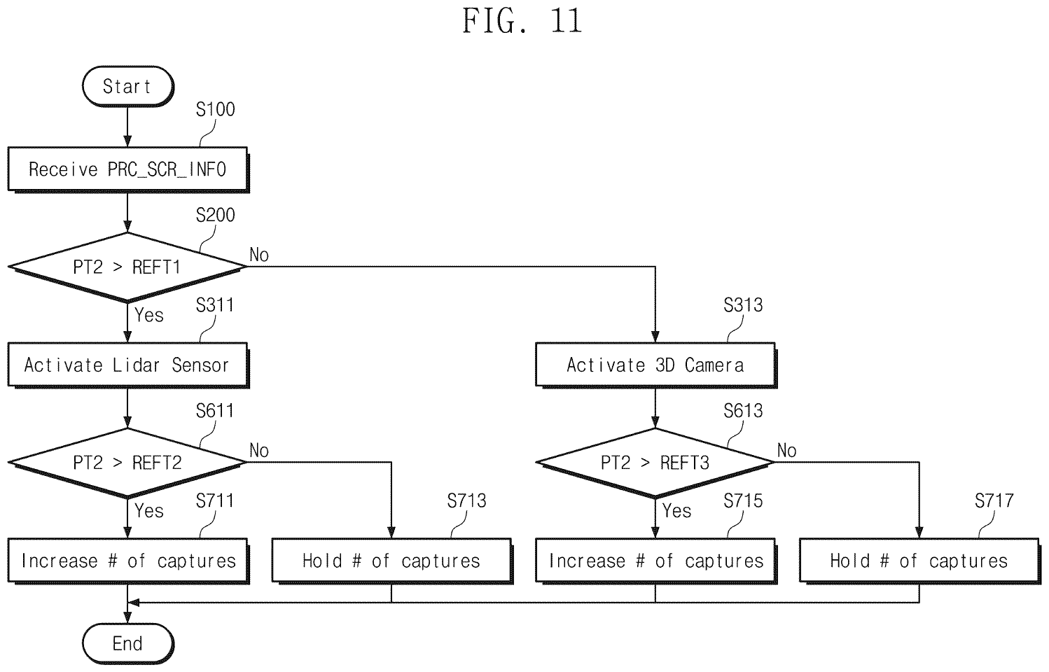

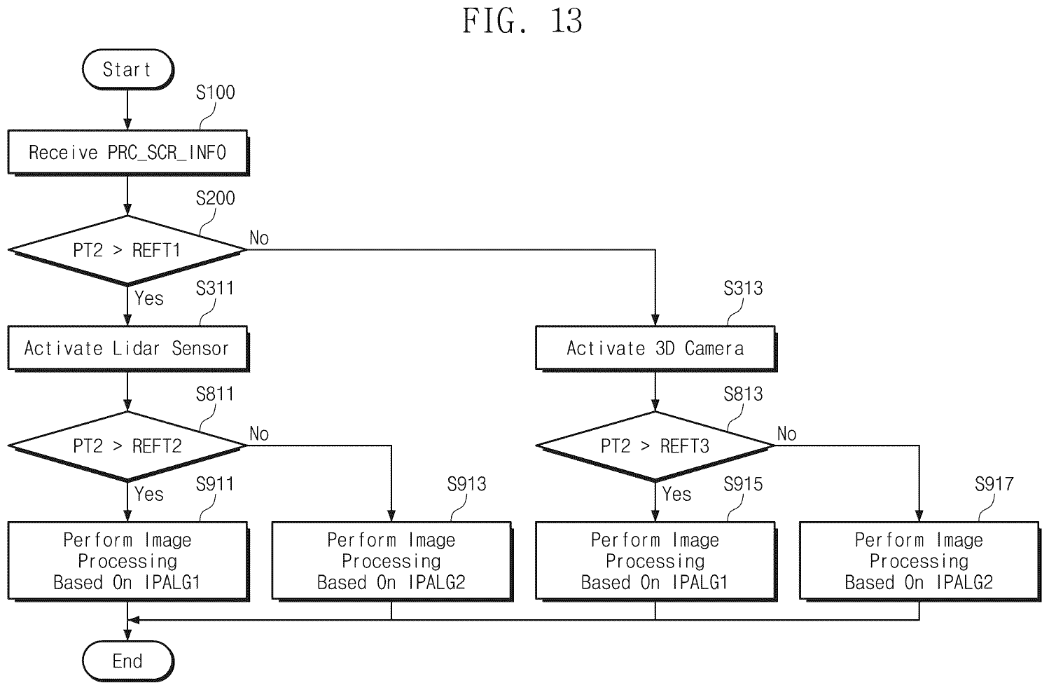

In an example embodiment, the process scenario information PRC_SCR_INFO may include a target post-process execution time which is a total execution time of the semiconductor post-processes, and may further include an execution time of the marking process and an execution time of remaining post-processes excluding the marking process. The execution time of the target post-process may vary, and in proportion to a change in the execution time of the target post-process, the execution time of the marking process and the like may also change. The processor 111 may compare the execution time of the changed marking process with one or more reference times to determine an activated second image capture device from among the plurality of second image capture devices 151-1 to 151-z. Operations in which the processor 111 activates one of the plurality of second image capture devices 151-1 to 151-z will be described later with reference to FIG. 3, FIG. 9, FIG. 11, FIG. 13, and the like.

In an example embodiment, the final three-dimensional image data may represent a predicted three-dimensional model for the semiconductor substrate including the plurality of semiconductor dies. For example, the test device 100 may generate a predicted three-dimensional model for one semiconductor substrate 170, may move the semiconductor substrate 170 (e.g., 171), and may generate a predicted three-dimensional model for a next semiconductor substrate 190. The test device 100 may generate the predicted three-dimensional model for the next semiconductor substrate 190, may move the semiconductor substrate 190 again (e.g., 191), and then may generate a predicted three-dimensional model for a next semiconductor substrate 193. The test device 100 may move the next semiconductor substrate 193 in the same manner as the semiconductor substrate 170 and the semiconductor substrate 190 (e.g., 195).

In an example embodiment, the marking process may be performed based on a three-dimensional model represented by the final three-dimensional image data. As the final three-dimensional image data more accurately represent the three-dimensional model with no or significantly fewer errors, the error which may occur in the marking process may be reduced or prevented.

The test device 100 may further include an adjustment circuit 112, an image acquisition circuit 113, an image processing circuit 114, and a determination circuit 115. The processor 111 may control the adjustment circuit 112 to control operations of the first image capture device 131 and the plurality of second image capture devices 151-1 to 151-z, and may control the image acquisition circuit 113 to store and to retain the two-dimensional image data output from the first image capture device 131 and the three-dimensional image data output from the plurality of second image capture devices 151-1 to 151-z. The processor 111 may control the image processing circuit 114 to perform various image processing for the two-dimensional image data and the three-dimensional image data, and may control the determination circuit 115 to perform comparison and judgment between the final three-dimensional image data and reference image data.

The processor 111 may control the components 112 to 115 of the test device 100 to activate one of the plurality of second image capture devices 151-1 to 151-z, and may also change a resolution of the activated second image capture device, or may change the number of three-dimensional image data generated by the activated second image capture device, and/or may select an image processing algorithm. The change in the resolution will be described later with reference to FIG. 9, the change in the number of three-dimensional image data will be described later with reference to FIG. 11, and the selection of the image processing algorithm will be described later with reference to FIG. 13.

With the above configuration, the test device according to some example embodiments of the present disclosure may generate the final three-dimensional image data for performing the marking process among the semiconductor post-processes by using the two-dimensional image data and the three-dimensional image data together. The test device may include the plurality of image capture devices capable of generating the three-dimensional image data when activated. By activating one of the plurality of image capture devices and generating the three-dimensional image data, the test device may adaptively acquire the three-dimensional image data which are a basis of the final three-dimensional image data. The final three-dimensional image data may more accurately represent the three-dimensional model depicting the semiconductor dies mounted on the semiconductor substrate with no or significantly fewer errors, and may more accurately identify a distortion and/or a bending of the semiconductor dies to efficiently reduce or prevent an error which may occur in the marking process due to the final three-dimensional image data.

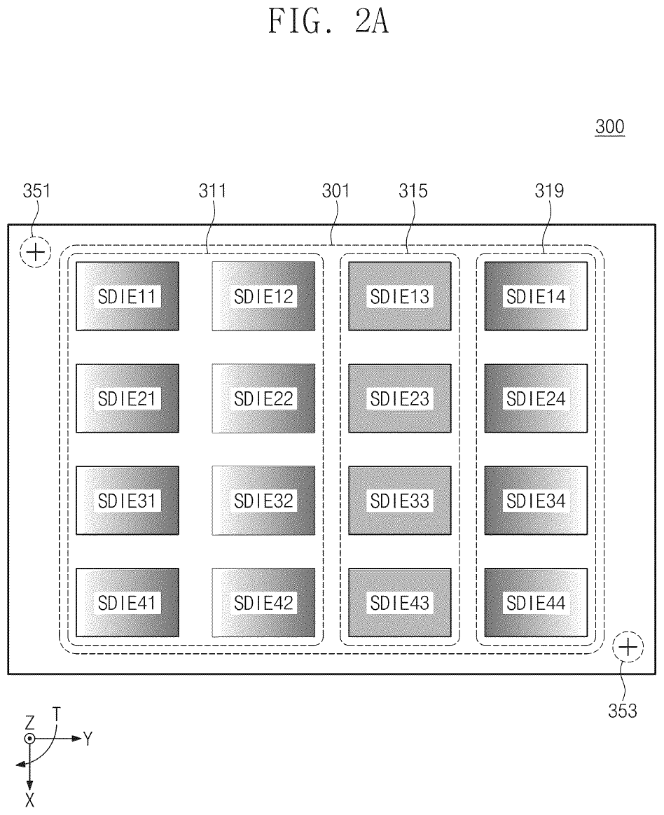

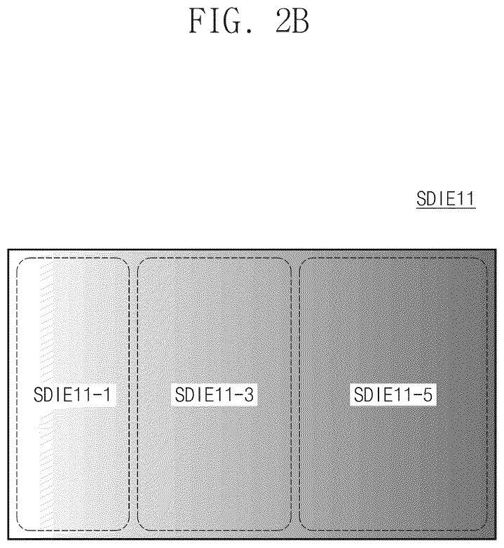

FIG. 2A is a diagram for explaining a semiconductor substrate of FIG. 1, according to an example embodiment, and FIG. 2B is a diagram for explaining a semiconductor die of FIG. 1, according to an example embodiment.

Referring to FIG. 2A, a semiconductor substrate 300 may include a plurality of semiconductor dies SDI11, SDIE12, SDIE13, SDIE14, SDIE21, SDIE22, SDIE23, SDIE24, SDIE31, SDIE32, SDIE33, SDIE34, SDIE41, SDIE42, SDIE43, and SDIE44, and may further include a marker 351 and a marker 353. The markers 351 and 353 may be used for matching between the two-dimensional image data and the three-dimensional image data described above with reference to FIG. 1, or may be used for comparison and determination between image data generated based on different semiconductor substrates (e.g., 170, 190, and 193).

In FIG. 2A, directions X, Y, Z, and T are illustrated. The X, Y, and Z directions may be perpendicular to each other, and the T direction may indicate a clockwise direction based on the Z direction. A bending or a curvature of a surface of each of the semiconductor dies SDIE11 to SDIE44 may be illustrated as an inner shadow in FIG. 2A.

In FIG. 2A, semiconductor dies having the same or similar shades may be classified as one group. For example, the semiconductor dies SDI11, SDI12, SDI21, SDI22, SDI31, SDI32, SDI41, and SDIE42 may be classified as one group 311, and the semiconductor dies SDI13, SDI23, SDI33, and SDIE43 may be classified as another group 315, and the semiconductor dies SDI14, SDI24, SDI34, and SDIE44 may be classified as the other group 319. The above classification may be related to the number of three-dimensional image data generated by the second image capture device (or the number of times in which a semiconductor substrate is captured by the second image capture device) as described below with reference to FIG. 11.

Referring to FIG. 2B, one of the semiconductor dies SDIE11 to SDIE44 of FIG. 2A is illustrated. The semiconductor die SDIE11 may have a shade. A relatively bright part (e.g., SDIE11-1) may be interpreted as a relatively protruding part from the surface of the semiconductor die SDIE11. A relatively dark part (e.g., SDIE11-5) may be interpreted as a relatively depressed part, and a part having intermediate brightness (e.g., SDIE11-3) may be interpreted as a part which is not protruding or not depressed between the SDI11-1 and the SDI11-5. According to the above interpretation, semiconductor dies having the same or similar characteristics may be classified as one group as described above with reference to FIG. 2A.

FIG. 3 is a flowchart illustrating an operating method of the test device of FIG. 1 according to an example embodiment.

Referring to FIG. 1 and FIG. 3, the processor 111 may receive the process scenario information PRC_SCR_INFO from the outside (operation S100).

In an example embodiment, the process scenario information PRC_SCR_INFO may include an execution time PT2 of the marking process among the semiconductor post-processes.

The processor 111 may activate one of the plurality of second image capture devices 151-1 to 151-z based on the execution time PT2 of the marking process and a first reference time REFT1 (operation S200, operation S311, and operation S313).

In an example embodiment, the plurality of second image capture devices 151-1 to 151-z may include image capture devices having different processing speeds. For example, the plurality of second image capture devices 151-1 to 151-z may include a three-dimensional camera and a light detection and ranging (LiDAR) sensor. For example, the three-dimensional camera may have a processing speed faster than a processing speed of the LiDAR sensor.

In an example embodiment, the processor 111 may activate the LiDAR sensor among the three-dimensional camera and the LiDAR sensor in response to that the execution time PT2 of the marking process is longer than the first reference time REFT1 (operation S311). That the execution time PT2 of the marking process is longer than the first reference time REFT1 may mean that a sufficient time is secured to normally perform the marking process even when the three-dimensional image data are generated by using the LiDAR sensor.

In an example embodiment, the processor 111 may activate the three-dimensional camera among the three-dimensional camera and the LiDAR sensor in response to that the execution time PT2 of the marking process is shorter than or equal to the first reference time REFT1 (operation S313).

FIG. 4 is a diagram for explaining a first image capture device and a plurality of second image capture devices of FIG. 1, according to an example embodiment.

Referring to FIG. 1 and FIG. 4, the first image capture device 131 may generate two-dimensional image data corresponding to a top view in the first direction 133, and each of the plurality of second image capture devices 151-1 to 151-z may generate three-dimensional image data corresponding to the oblique views in the second directions 153-1 to 153-m.

For example, the first image capture device 131 may be the two-dimensional camera, and the plurality of second image capture devices 151-1 to 151-z may include the three-dimensional camera and the LiDAR sensor.

For example, in terms of processing speed, the two-dimensional camera may be the fastest, the three-dimensional camera may be faster than the LiDAR sensor, and the LiDAR sensor may be slower than the three-dimensional camera.

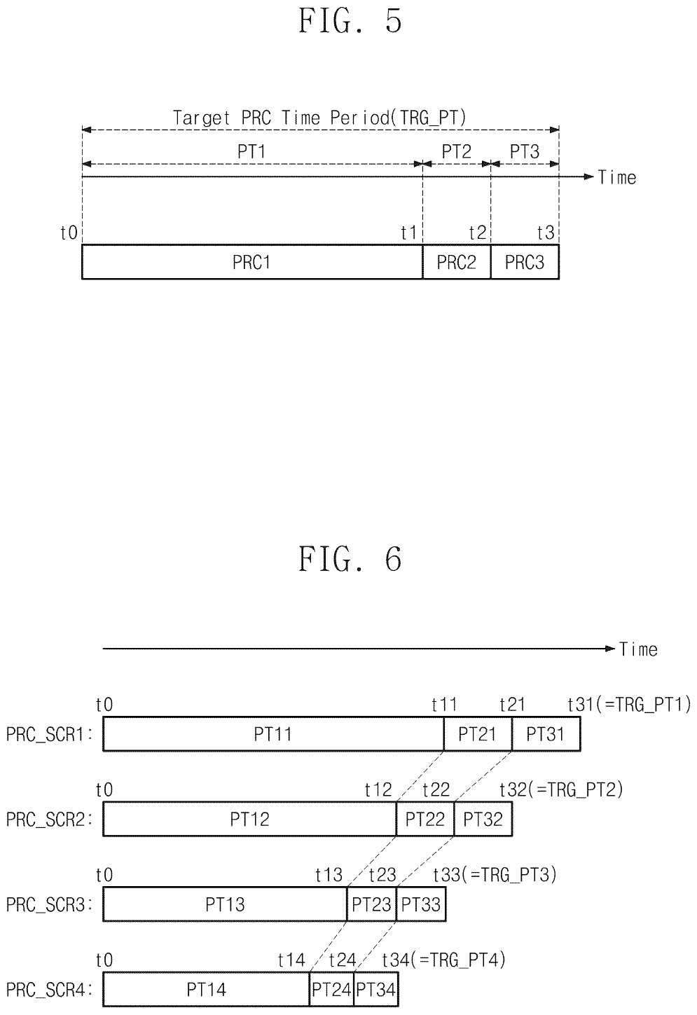

FIG. 5 is a diagram for explaining a target post-process execution time included in process scenario information of FIG. 1 according to an example embodiment.

Referring to FIG. 1 and FIG. 5, the process scenario information PRC_SCR_INFO may include a target post-process execution time TRG_PT, which is the total execution time of the semiconductor post-processes. For example, the semiconductor post-processes may be performed through sequential execution time points t0, t1, t2, and t3, may include a marking process PRC2 performed from the time point t1 to the time point t2, and may further include first post-processes PRC1 performed from the time point t0 to the time point t1 before the marking process PRC2, and second post-processes PRC3 performed from the time point t2 to the time point t3 after the marking process PRC2.

In an example embodiment, an execution time PT1 (e.g., t1−t0) may be secured as the execution time of the first post-processes PRC1, the execution time PT2 (e.g., t2−t1) may be secured as the execution time of the marking process PRC2, and an execution time PT3 (e.g., t3−t2) may be secured as the execution time of the second post-processes PRC3.

In an example embodiment, the sum of the execution times PT1, PT2, and PT3 may be the target post-process execution time TRG_PT, and the target post-process execution time TRG_PT may be the total execution time of the semiconductor post-processes allowed for a specific semiconductor die.

FIG. 6 is a diagram for explaining a change in a target post-process execution time of FIG. 5, according to an example embodiment.

Referring to FIG. 1, FIG. 5, and FIG. 6, the target post-process execution time TRG_PT may be changed based on a process scenario indicated by the process scenario information PRC_SCR_INFO. For example, when the process scenario is a PRC_SCR1, the semiconductor post-processes may be performed through time points t0, t11, t21, and t31, and in this case, the target post-process execution time TRG_PT may be a TRG_PT1. When the process scenario is a PRC_SCR2, the semiconductor post-processes may be performed through time points t0, t12, t22, and t32, and in this case, the target post-process execution time TRG_PT may be a TRG_PT2. When the process scenario is a PRC_SCR3, the semiconductor post-processes may be performed through time points t0, t13, t23, and t33, and in this case, the target post-process execution time TRG_PT may be a TRG_PT3. When the process scenario is a PRC_SCR4, the semiconductor post-processes may be performed through time points t0, t14, t24, and t34, and in this case, the target post-process execution time TRG_PT may be a TRG_PT4.

In an example embodiment, as the process scenario sequentially changes in the order of the PRC_SCR1, the PRC_SCR2, the PRC_SCR3, and the PRC_SCR4, the target post-process execution time TRG_PT may sequentially change in the order of the TRG_PT1, the TRG_PT2, the TRG_PT3, and the TRG_PT4.

For example, the execution time of the first post-processes PRC1, the execution time of the marking process PRC2, and the execution time of the second post-processes PRC3 may vary in proportion to the change in the target post-process execution time TRG_PT.

For example, as the target post-process execution time TRG_PT is shortened, the execution time of the first post-processes PRC1 may be shortened in the order of a PT11, a PT12, a PT13, and a PT14, the execution time of the marking process PRC2 may be shortened in the order of a PT21, a PT22, a PT23, and a PT24, and the execution time of the second post-processes PRC3 may be shortened in the order of a PT31, a PT32, a PT33, and a PT34.

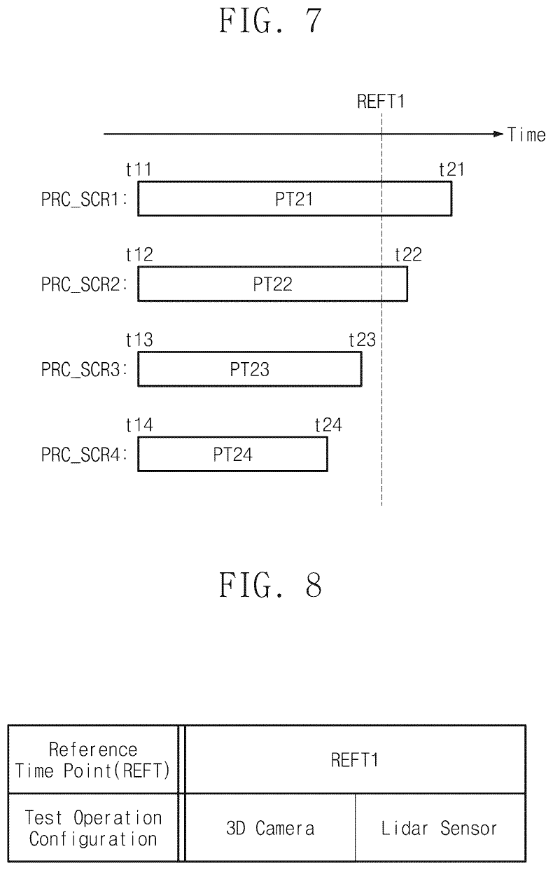

FIG. 7 is a diagram for explaining a reference time related to a marking process of FIG. 6, according to an example embodiment.

Referring to FIG. 3, FIG. 6, and FIG. 7, the first reference time REFT1 described above with reference to FIG. 3 may be set.

As the process scenario sequentially changes in the order of the PRC_SCR1, the PRC_SCR2, the PRC_SCR3, and the PRC_SCR4, the execution time of the marking process PRC2 may be shortened in the order of the PT21, the PT22, the PT23, and the PT24.

In an example embodiment, the first reference time REFT1 may be set from a time point (e.g., t11, t12, t13, or t14) when the marking process PRC2 starts for each of the process scenario.

In an example embodiment, the first reference time REFT1 may be shorter than the PT21 or the PT22 when the process scenario is the PRC_SCR1 or the PRC_SCR2, and may be longer than the PT23 or the PT24 when the process scenario is the PRC_SCR3 or the PRC_SCR4.

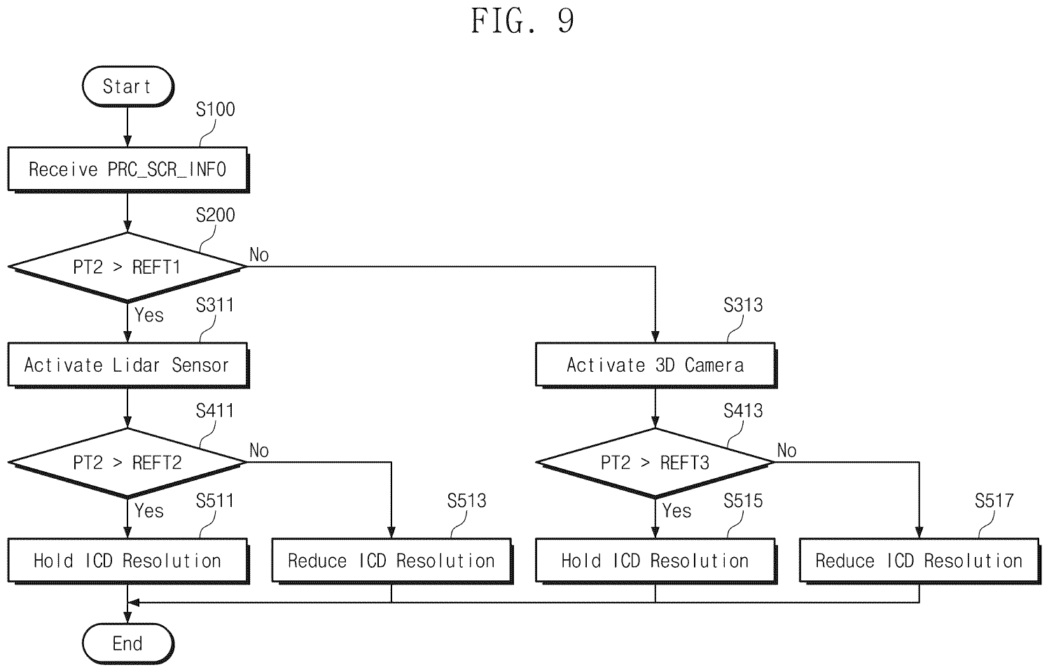

FIG. 8 is a diagram explaining that a processor of FIG. 1 activates one of a plurality of second image capture devices based on a reference time of FIG. 7, according to an example embodiment.

In FIG. 8, the right side of the first reference time REFT1 may mean a case where the execution time of the marking process is longer than the first reference time REFT1, and the left side of the first reference time REFT1 may mean a case where the execution time of the marking process is shorter than the first reference time REFT1.

Referring to FIG. 1, FIG. 7, and FIG. 8, the processor 111 may activate one of the plurality of second image capture devices 151-1 to 151-z based on the first reference time REFT1.

In an example embodiment, as described above with reference to FIG. 3 and FIG. 4, the plurality of second image capture devices 151-1 to 151-z may include the three-dimensional camera and the LiDAR sensor. For example, the processor 111 may activate the LiDAR sensor in response to that the execution time of the marking process is longer than the first reference time REFT1. For example, the processor 111 may activate the three-dimensional camera in response to that the execution time of the marking process is shorter than or equal to the first reference time REFT1.

In an example embodiment, the test operation configuration of FIG. 8 may mean the configuration of the test device 100 of FIG. 1 for performing the above-described operation S100, operation S200, operation S311, and operation S313 with reference to FIG. 3 for the marking process.

FIG. 9 is a flowchart illustrating an operating method of the test device of FIG. 1, according to an example embodiment.

The operations illustrated in FIG. 9 may further include operation S411, operation S413, operation S511, operation S513, operation S515, and operation S517 as compared with the operations illustrated in FIG. 3. A duplicate description will be omitted.

Referring to FIG. 1, FIG. 3, and FIG. 9, the processor 111 may receive the process scenario information PRC_SCR_INFO from the outside (operation S100).

The processor 111 may activate the LiDAR sensor among the three-dimensional camera and the LiDAR sensor (operation S311) in response to that the execution time PT2 of the marking process is longer than the first reference time REFT1 (operation S200: YES). The processor 111 may activate the three-dimensional camera among the three-dimensional camera and the LiDAR sensor (operation S313) in response to that the execution time PT2 of the marking process is shorter than or equal to the first reference time REFT1 (operation S200: NO).

In an example embodiment, after operation S311, the processor 111 may maintain a resolution of the second image capture device (operation S511) in response to that the execution time PT2 of the marking process is longer than a second reference time REFT2 (operation S411: YES). That the execution time PT2 of the marking process is longer than the second reference time REFT2 may mean that a sufficient time for normally performing the marking process is secured even though the resolution of the second image capture device is maintained.

In an example embodiment, the processor 111 may reduce the resolution of the second image capture device (operation S513) in response to that the execution time PT2 of the marking process is shorter than or equal to the second reference time REFT2 (operation S411: NO).

In an example embodiment, after operation S313, the processor 111 may maintain the resolution of the second image capture device (operation S515) in response to that the execution time PT2 of the marking process is longer than a third reference time REFT3 (operation S413: YES).

In an example embodiment, the processor 111 may reduce the resolution of the second image capture device (operation S517) in response to that the execution time PT2 of the marking process is shorter than or equal to the third reference time REFT3 (operation S413: NO).

FIG. 10 is a diagram for explaining reference times related to the marking process of FIG. 9, according to an example embodiment.

Referring to FIG. 3, FIG. 6, FIG. 7, and FIG. 10, the first reference time REFT1, the second reference time REFT2, and the third reference time REFT3 described above with reference to FIG. 9 may be set.

As the process scenario sequentially changes in the order of the PRC_SCR1, the PRC_SCR2, the PRC_SCR3, and the PRC_SCR4, the execution time of the marking process PRC2 may be shortened in the order of the PT21, the PT22, the PT23, and the PT24.

In an example embodiment, the first reference time REFT1, the second reference time REFT2, and the third reference time REFT3 may be set from a time point (e.g., t11, t12, t13, or t14) when the marking process PRC2 starts for each of the process scenario.

In an example embodiment, the first reference time REFT1 may be shorter than the PT21 or the PT22 when the process scenario is the PRC_SCR1 or the PRC_SCR2, and may be longer than the PT23 or the PT24 when the process scenario is the PRC_SCR3 or the PRC_SCR4.

In an example embodiment, the second reference time REFT2 may be shorter than the PT21 when the process scenario is the PRC_SCR1, and may be longer than the PT22, the PT23, or the PT24 when the process scenario is the PRC_SCR2, the PRC_SCR3, or the PRC_SCR4.

In an example embodiment, the third reference time REFT3 may be shorter than the PT21, the PT22, or the PT23 when the process scenario is the PRC_SCR1, the PRC_SCR2, or the PRC_SCR3, and may be longer than the PT24 when the process scenario is the PRC_SCR4.

FIG. 11 is a flowchart illustrating an operating method of the test device of FIG. 1, according to an example embodiment.

The operations illustrated in FIG. 11 may further include operation S611, operation S613, operation S711, operation S713, operation S715, and operation S717 as compared with the operations illustrated in FIG. 3. A duplicate description will be omitted.

Referring to FIG. 1, FIG. 3, and FIG. 11, the processor 111 may receive the process scenario information PRC_SCR_INFO from the outside (operation S100).

The processor 111 may activate the LiDAR sensor among the three-dimensional camera and the LiDAR sensor (operation S311) in response to that the execution time PT2 of the marking process is longer than the first reference time REFT1 (operation S200: YES). The processor 111 may activate the three-dimensional camera among the three-dimensional camera and the LiDAR sensor (operation S313) in response to that the execution time PT2 of the marking process is shorter than or equal to the first reference time REFT1 (operation S200: NO).

In an example embodiment, after operation S311, the processor 111 may increase the number of capturing times of the second image capture device (operation S711) in response to that the execution time PT2 of the marking process is longer than the second reference time REFT2 (operation S611: YES). That the execution time PT2 of the marking process is longer than the second reference time REFT2 may mean that the sufficient time for normally performing the marking process is secured even though the number of capturing times of the second image capture device is increased.

In an example embodiment, the processor 111 may maintain the number of capturing times of the second image capture device (operation S713) in response to that the execution time PT2 of the marking process is shorter than or equal to the second reference time REFT2 (operation S611: NO).

In an example embodiment, after operation S313, the processor 111 may increase the number of capturing times of the second image capture device (operation S715) in response to that the execution time PT2 of the marking process is longer than the third reference time REFT3 (operation S613: YES).

In an example embodiment, the processor 111 may maintain the number of captures of the second image capture device (operation S717) in response to that the execution time PT2 of the marking process is shorter than or equal to the third reference time REFT3 (operation S613: NO).

In an example embodiment, increasing the number of capturing times of the image capture device in operation S711 and operation S715 may mean generating the three-dimensional image data for each group described above with reference to FIG. 2A. In this case, the processor 111 may move the second image capture device whenever the second image capture device captures the semiconductor substrate.

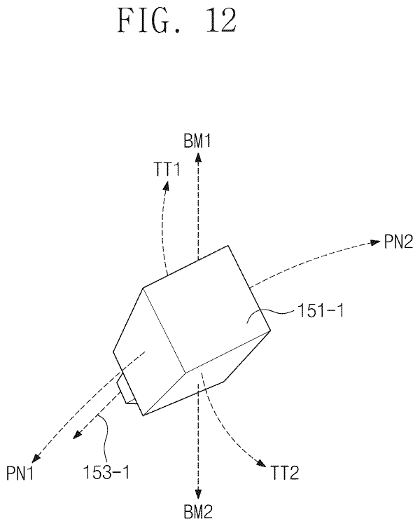

FIG. 12 is a diagram for explaining a movement of a second image capture device in association with an increase in the number of capturing times of FIG. 11.

In FIG. 12, one (e.g., 151-1) of the plurality of second image capture devices 151-1 to 151-z illustrated in FIG. 1 is shown as an example.

Referring to FIG. 11 and FIG. 12, the second image capture device 151-1 may move through tilt movements TT1 and TT2, panning movements PN1 and PN2, and boom movements BM1 and BM2, and may capture semiconductor dies included in each group included in a semiconductor substrate under the same or similar conditions by the movement. For example, the semiconductor dies included in each group may be captured at the same distance in the same direction by the movement.

FIG. 13 is a flowchart illustrating an operating method of the test device of FIG. 1, according to an example embodiment.

The operations illustrated in FIG. 13 may further include operation S811, operation S813, operation S911, operation S913, operation S915, and operation S917, as compared with the operations illustrated in FIG. 3. A duplicate description will be omitted.

Referring to FIG. 1, FIG. 3, and FIG. 13, the processor 111 may receive the process scenario information PRC_SCR_INFO from the outside (operation S100).

The processor 111 may activate the LiDAR sensor among the three-dimensional camera and the LiDAR sensor (operation S311) in response to that the execution time PT2 of the marking process is longer than the first reference time REFT1 (operation S200: YES). The processor 111 may activate the three-dimensional camera among the three-dimensional camera and the LiDAR sensor (operation S313) in response to that the execution time PT2 of the marking process is shorter than or equal to the first reference time REFT1 (operation S200: NO).

In an example embodiment, after operation S311, the processor 111 may perform the image processing for the three-dimensional image data based on a first image processing algorithm among a first image processing algorithm IPALG1 and a second image processing algorithm IPALG2 (operation S911) in response to that the execution time PT2 of the marking process is longer than the second reference time REFT2 (operation S811: YES). A processing speed of the first image processing algorithm IPALG1 may be slower than a processing speed of the second image processing algorithm IPALG2. That the execution time PT2 of the marking process is longer than the second reference time REFT2 may mean that the sufficient time for normally performing the marking process is secured even though the image processing for the three-dimensional image data is performed based on the first image processing algorithm IPALG1.

In an example embodiment, the processor 111 may perform the image processing for the three-dimensional image data based on the second image processing algorithm IPALG2 (operation S913) in response to that the execution time PT2 of the marking process is shorter than or equal to the second reference time REFT2 (operation S811: NO).

In an example embodiment, after operation S313, the processor 111 may perform the image processing for the three-dimensional image data based on the first image processing algorithm IPALG1 (operation S915) in response to that the execution time PT2 of the marking process is longer than the third reference time REFT3 (operation S813: YES).

In an example embodiment, the processor 111 may perform the image processing for the three-dimensional image data based on the second image processing algorithm IPALG2 (operation S917) in response to that the execution time PT2 of the marking process is shorter than or equal to the third reference time REFT3 (operation S813: NO).

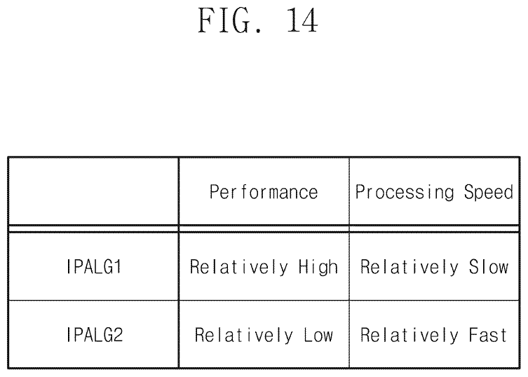

FIG. 14 is a diagram for explaining image processing algorithms associated with image processing of FIG. 13.

Referring to FIG. 13 and FIG. 14, the first image processing algorithm IPALG1 and the second image processing algorithm IPALG2 may be compared in terms of “performance” and “processing speed”.

In an example embodiment, the “performance” of the first image processing algorithm IPALG1 may be higher than the “performance” of the second image processing algorithm IPALG2.

In an example embodiment, the “processing speed” of the first image processing algorithm IPALG1 may be slower than the “processing speed” of the second image processing algorithm IPALG2.

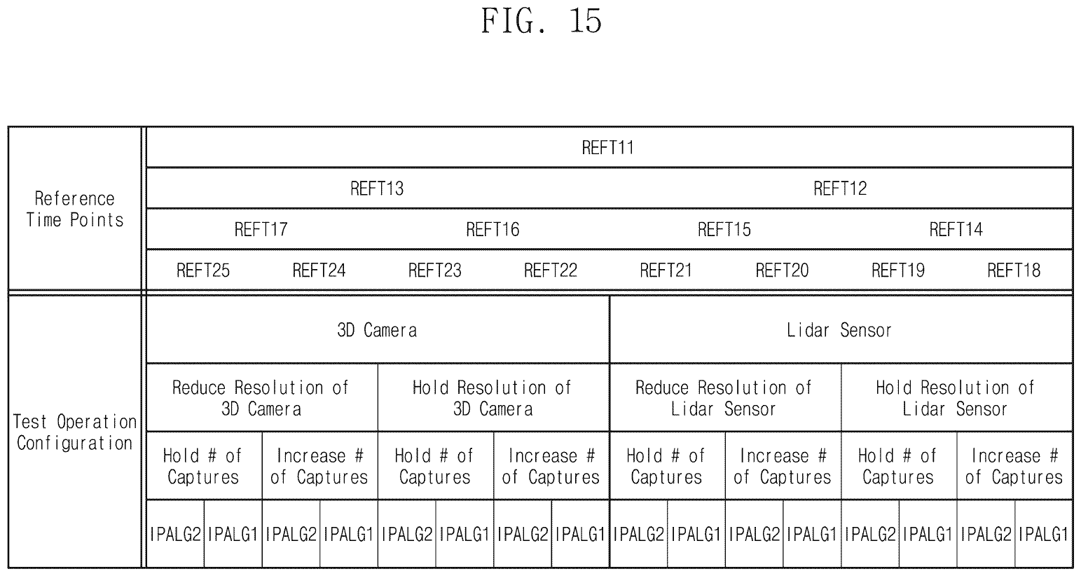

FIG. 15 is a diagram illustrating an operating method of the test device of FIG. 1, according to an example embodiment.

As described above with reference to FIG. 1, FIG. 3, FIG. 9, FIG. 11, and FIG. 13, in the operating method of the test device according to some example embodiments of the present disclosure, based on the process scenario information PRC_SCR_INFO, one of the plurality of second image capture devices 151-1 to 151-z may be activated, or the resolution of the activated second image capture device may be reduced or maintained. Additionally, the number of capturing times of the activated second image capture device may be increased or maintained, or the image processing may be performed on the three-dimensional image data based on one of the first image processing algorithm and the second image processing algorithm.

In spite of the above descriptions, in the operating method of the test device according to some example embodiments of the present disclosure, the operations described in FIG. 3, FIG. 9, FIG. 11, and FIG. 13 may be appropriately combined. For example, operation S611, operation S613, operation S711, operation S713, operation S715, and operation S717 described above with reference to FIG. 11 may be performed together with operation S100, operation S200, operation S311, and operation S313 described above with reference to FIG. 3 and operation S411, operation S413, operation S511, operation S513, operation S515 and operation S517 described above with reference to FIG. 9. However, example embodiments of the present disclosure are not limited thereto, and various types of modified example embodiments may be derived from the present disclosure.

Referring to FIG. 1 and FIG. 15, reference times REFT11, REFT12, REFT13, REFT14, REFT15, REFT16, REFT17, REFT18, REFT19, REFT20, REFT21, REFT22, REFT23, REFT24, and REFT25 may be set.

The right side of each of the reference times REFT11 to REFT25 illustrated in FIG. 15 may mean a case where the execution time of the marking process is longer than a corresponding reference time, and the left side of each of the reference times REFT11 to REFT25 may mean a case where the execution time of the marking process is shorter than a corresponding reference time. An example embodiment illustrated in FIG. 15 may also be interpreted based on the method described above with reference to FIG. 9.

In an example embodiment, as described above with reference to FIG. 3 and FIG. 4, the plurality of second image capture devices 151-1 to 151-z may include the three-dimensional camera and the LiDAR sensor.

In an example embodiment, the processor 111 may activate the LiDAR sensor in response to that the execution time of the marking process is longer than the reference time REFT11. The processor 111 may maintain the resolution of the LiDAR sensor in response to that the execution time of the marking process is longer than the reference time REFT12. The processor 111 may increase the number of capturing times of the LiDAR sensor in response to that the execution time of the marking process is longer than the reference time REFT14. The processor 111 may perform the image processing for the three-dimensional image data based on the first image processing algorithm in response to that the execution time of the marking process is longer than the reference time REFT18.

It will be apparent to those skilled in the art that various test methods according to some example embodiments of the present disclosure may be performed based on the reference times REFT11, REFT12, REFT13, REFT14, REFT15, REFT16, REFT17, REFT18, REFT19, REFT20, REFT21, REFT22, REFT23, REFT24, and REFT25. A duplicate description will be omitted.

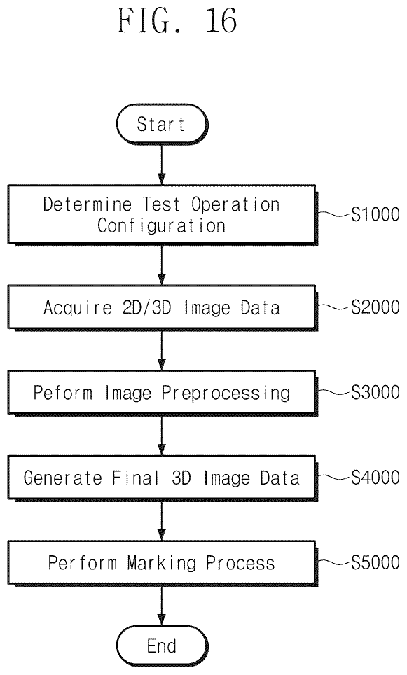

FIG. 16 is a flowchart illustrating an operating method of a test device and subsequent operations, according to an example embodiment of the present disclosure.

Referring to FIG. 16, the configuration of the test operation may be determined (operation S1000).

In an example embodiment, the test operation configuration may mean the operations or the configurations described above with reference to FIG. 8 or FIG. 15. For example, the test operation configuration may include the configurations according to the operations described above with reference to FIG. 1, FIG. 3, FIG. 9, FIG. 11, and/or FIG. 13.

The two-dimensional image data and the three-dimensional image data may be acquired (operation S2000).

In an example embodiment, the two-dimensional image data and the three-dimensional image data may be generated based on one of the first image capture device 131 and the plurality of second image capture devices 151-1 to 151-z described above with reference to FIG. 1.

The image processing may be performed (operation S3000).

In an example embodiment, the image processing may include a noise removal, a timestamping, an alignment, and the like for the two-dimensional image data and the three-dimensional image data. For example, in the alignment, the markers 351 and 353 described above with reference to FIG. 2A may be used.

In an example embodiment, the image processing may further include a calculation of a transformation matrix for synthesizing the two-dimensional image data and the three-dimensional image data, a calculation of point clouds from the three-dimensional image data, a mapping based on global coordinates, and the like.

In an example embodiment, the image processing may include a point cloud stitching algorithm.

The final three-dimensional image data may be generated (operation S4000).

In an example embodiment, the final three-dimensional image data may represent the three-dimensional model which is predicted for the semiconductor substrate including the plurality of semiconductor dies.

The marking process may be performed (operation S5000).

In an example embodiment, the marking process may be performed based on the three-dimensional model represented by the final three-dimensional image data. As the final three-dimensional image data more accurately represent the three-dimensional model with no or significantly fewer errors, the error which may occur in the marking process may be reduced or prevented. Further, after performing the marking process, a sawing process may be performed to divide a plurality of semiconductor dies mounted on the semiconductor substrate into individual semiconductor chips.

As described above, the test device according to some example embodiments of the present disclosure may generate the final three-dimensional image data for performing the marking process among the semiconductor post-processes by using the two-dimensional image data and the three-dimensional image data together. The test device may include the plurality of image capture devices capable of generating the three-dimensional image data when activated, and may adaptively acquire the three-dimensional image data, which serves as the basis of the final three-dimensional image data, by activating one of the plurality of image capture devices. The final three-dimensional image data may more accurately represent the three-dimensional model depicting the semiconductor dies mounted on the semiconductor substrate with no or significantly fewer errors, and may efficiently reduce or prevent an error which may occur in the marking process due to the final three-dimensional image data, by more accurately identifying the distortion and/or the bending of the semiconductor dies.

The above description is specific example embodiments for implementing the present disclosure. The present disclosure will include not only the above-described example embodiments, but also some other example embodiments which may be simply designed or easily changed. In addition, the above-described example embodiments of the present disclosure may be easily modified and implemented. Accordingly, the present disclosure should not be limited to the above-described example embodiments and should be determined by the claims described below as well as those equivalent to the claims of this disclosure.

A test device according to some example embodiments of the present disclosure may generate final three-dimensional image data for performing a marking process among semiconductor post-processes by using two-dimensional image data and three-dimensional image data together. The test device may include a plurality of image capture devices capable of generating three-dimensional image data when activated, and may adaptively acquire three-dimensional image data, which serve as the basis of the final three-dimensional image data by activating one of the plurality of image capture devices. The final three-dimensional image data may more accurately represent a three-dimensional model depicting semiconductor dies mounted on a semiconductor substrate with no or significantly fewer errors, and it is possible to efficiently reduce or prevent errors which may occur in the marking process due to the final three-dimensional image data, by more accurately identifying a distortion and/or a bending of semiconductor dies.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the present disclosure has been described with reference to some example embodiments thereof, it will be apparent to those of ordinary skill in the art that various changes and modifications may be made thereto without departing from the spirit and scope of the present disclosure as set forth in the following claims.

What is claimed is:

1. A test device comprising:
a first image capture device configured to capture a semiconductor substrate including a plurality of semiconductor dies and generate two-dimensional image data;
a plurality of second image capture devices each configured to capture the semiconductor substrate and generate three-dimensional image data when activated; and
a processor configured to
activate one of the plurality of second image capture devices based on process scenario information related to semiconductor post-processes, the semiconductor post-processes including a marking process for the plurality of semiconductor dies, and
generate final three-dimensional image data for performing the marking process based on the two-dimensional image data and the three-dimensional image data.

2. The test device of claim 1, wherein
the plurality of second image capture devices include a three-dimensional camera and a light detection and ranging (LiDAR) sensor having different processing speeds, and
the process scenario information includes a target post-process execution time including an execution time of the marking process.

3. The test device of claim 2, wherein the processor is configured to activate one of the plurality of second image capture devices based on the execution time of the marking process and a first reference time.

4. The test device of claim 3, wherein the processor is configured to activate the LiDAR sensor in response to the execution time of the marking process being longer than the first reference time.

5. The test device of claim 2, wherein the processor is configured to:
activate one of the plurality of second image capture devices based on the execution time of the marking process, a first reference time, and a second reference time; and
change a resolution of the activated one of the plurality of second image capture devices.

6. The test device of claim 5, wherein the processor is configured to:
activate the LiDAR sensor in response to the execution time of the marking process being longer than the first reference time; and
reduce a resolution of the LiDAR sensor in response to the execution time of the marking process being shorter than or equal to the second reference time,
wherein the second reference time is longer than the first reference time.

7. The test device of claim 2, wherein the processor is configured to:
activate one of the plurality of second image capture devices based on the execution time of the marking process, a first reference time, and a second reference time; and
change a number of three-dimensional image data which the activated one of the plurality of second image capture devices generates.

8. The test device of claim 7, wherein the processor is configured to:
activate the LiDAR sensor in response to the execution time of the marking process being longer than the first reference time; and
increase a number of captures of the LiDAR sensor in response to the execution time of the marking process being longer than the second reference time,
wherein the second reference time is longer than the first reference time.

9. The test device of claim 8, wherein the processor is configured to move the LiDAR sensor based on the increased number of captures of the LiDAR sensor, whenever the LiDAR sensor captures the semiconductor substrate.

10. The test device of claim 2, wherein the processor is configured to:
activate one of the plurality of second image capture devices based on the execution time of the marking process, a first reference time, and a second reference time; and
perform image processing for the three-dimensional image data based on one of a first image processing algorithm and a second image processing algorithm.

11. The test device of claim 10, wherein the processor is configured to:
activate the LiDAR sensor in response to the execution time of the marking process being longer than the first reference time; and
perform the image processing for the three-dimensional image data based on the first image processing algorithm in response to the execution time of the marking process being longer than the second reference time,
wherein the second reference time is longer than the first reference time, and
wherein a processing speed of the first image processing algorithm is slower than a processing speed of the second image processing algorithm.

12. The test device of claim 2, wherein the processor is configured to:
activate one of the plurality of second image capture devices based on the execution time of the marking process, a first reference time, a second reference time, and a third reference time;
change a resolution of the activated one of the plurality of second image capture devices; and
change a number of three-dimensional image data which the activated one of the plurality of second image capture devices generates.

13. The test device of claim 12, wherein the processor is configured to:
activate the LiDAR sensor in response to the execution time of the marking process being longer than the first reference time;
reduce a resolution of the LiDAR sensor in response to the execution time of the marking process being shorter than or equal to the second reference time; and
increase a number of captures of the LiDAR sensor in response to the execution time of the marking process being longer than the third reference time,
wherein the second reference time is longer than the first reference time, and
wherein the third reference time is longer than the first reference time and shorter than the second reference time.

14. The test device of claim 2, wherein the target post-process execution time includes:
a first execution time of first post-processes before the marking process among the semiconductor post-processes;
the execution time of the marking process; and
a second execution time of second post-processes after the marking process among the semiconductor post-processes.

15. The test device of claim 14, wherein the first execution time of the first post-processes, the execution time of the marking process, and the second execution time of the second post-processes change in proportion to a change in the target post-process execution time.

16. A method of operating a test device, the method comprising:
activating a first image capture device;
activating one of a plurality of second image capture devices based on process scenario information related to semiconductor post-processes, the semiconductor post-processes including a marking process for a plurality of semiconductor dies;
generating two-dimensional image data by the first image capture device;
generating three-dimensional image data by the activated one of the plurality of second image capture devices; and
generating final three-dimensional image data for performing the marking process based on the two-dimensional image data and the three-dimensional image data.

17. The method of claim 16, wherein
the plurality of second image capture devices include three-dimensional cameras and LiDAR sensors having different processing speeds, and
the process scenario information includes a target post-process execution time including an execution time of the marking process.

18. The method of claim 17, further comprising:
determining a test operation configuration based on the process scenario information.

19. The method of claim 18, wherein the determining of the test operation configuration includes selecting one of the plurality of second image capture devices based on the execution time of the marking process and a first reference time.

20. A test device comprising:
a first image capture device configured to capture a semiconductor substrate including a plurality of semiconductor dies and generate two-dimensional image data;
a plurality of second image capture devices, each configured to capture the semiconductor substrate and generate three-dimensional image data when activated; and
a processor configured to
activate one of the plurality of second image capture devices based on an execution time of a marking process for the plurality of semiconductor dies and a plurality of reference times, and
generate final three-dimensional image data for performing the marking process based on the two-dimensional image data and the three-dimensional image data.
